(19) United States
(12) Patent Application Publication
(10) Pub. No.: US 2021/0184062 A1
(43) Pub. Date: Jun. 17, 2021

(54) AUTOMOTIVE SOLAR CELL ROOF PANEL USING LAMINATED GLASS

(71) Applicants: Hyundai Motor Company, Seoul (KR); Kia Motors Corporation, Seoul (KR)

(72) Inventors: Eun Yeong Lee, Seoul (KR); Sang Hak Kim, Seoul (KR); Mi Yeon Song, Seoul (KR)

(21) Appl. No.: 17/107,308

(22) Filed: Nov. 30, 2020

(30) Foreign Application Priority Data
Dec. 13, 2019 (KR) 10-2019-0166591

(51) Int. Cl. H01L 31/05; H02S 20/30; B60L 8/00

(52) U.S. Cl. CPC H01L 31/0504; H01L 31/022466; B60L 8/003; H02S 20/30

(57) ABSTRACT

Disclosed herein is an automotive solar cell roof panel which may be manufactured by adjusting the width and number of cells according to a transparent part and an opaque part in one solar cell module, thus improving output and simplifying a structure. The first and second solar cells include a plurality of transparent-part cells and a plurality of opaque-part cells whose widths and numbers are adjusted according to a current density and a voltage ratio. As such, it is unnecessary to array different kinds of solar cells with different voltage or current ranges, thus maximizing output in one solar cell module, and an additional wiring structure for individually controlling output power, an additional converter, and additional control for voltage matching may not be required, thus simplifying a process.

### CROSS REFERENCE TO RELATED APPLICATION

The present application claims priority to Korean Patent Application No. 10-2019-0166591, filed Dec. 13, 2019, the entire contents of which are incorporated herein for all purposes by this reference.

### TECHNICAL FIELD

The present invention relates to an automotive solar cell roof panel manufactured by adjusting the width and number of cells of a transparent part and an opaque part in one solar cell module, thus improving output and simplifying a structure.

### BACKGROUND OF THE INVENTION

Recently, eco-friendly vehicles such as hybrid vehicles, electric cars, and fuel cell vehicles have been developed substantially and various efforts have been made to apply solar cells to these vehicle models.

For example, when a semi-transparent solar cell is applied to a sunroof panel or a panoramic sunroof panel of a vehicle, this can realize the openness of an existing sunroof and utilizes solar energy in various application fields, so that attempts have been being made to apply the semi-transparent solar cell to the sunroof panel and the panoramic sunroof panel of the vehicle.

Generally, a sunroof or panoramic roof of a vehicle is composed of tempered glass and a frame. In order to make the frame of a vehicle interior, an electrode connected to a solar cell, and a wire part invisible from an outside, an outer region of the tempered glass is coated with ceramics.

In the case of an existing silicon solar cell roof panel equipped with a crystalline silicon solar cell, the crystalline silicon solar cell is mounted on a central portion (a central portion of tempered glass to which ceramic coating is not applied) on a back of the roof panel. However, this has not been widely used due to problems including price, openness, and poor design, so that attempts have been made to replace the crystalline silicon solar cell with an amorphous silicon solar cell.

Since the amorphous silicon solar cell has several advantages in that it may be made of a transparent electrode and it is possible to make various patterns of solar cells, many studies have been conducted to apply the amorphous silicon solar cell to various application fields.

The amorphous silicon solar cell is advantageous in that it is less expensive than the crystalline silicon solar cell and has openness, and it is possible to apply various colors thereto. However, the amorphous silicon solar cell is disadvantageous in that it is lower in performance than the crystalline silicon solar cell.

As such, different kinds of solar cells have different energy efficiency. Thus, in the case of connecting a driving part and a charging part using one wire part to come into contact with each solar cell, a total voltage value produced from the solar cells can converge to the same extent as the solar cell having a small voltage value. Therefore, in the case of using different kinds of solar cells, this may be problematic in that energy efficiency is lowered due to contact between the solar cells. Furthermore, even if the output power is individually controlled in order to solve a reduction in energy efficiency when using different kinds of solar cells, an additional wiring structure for an array, an additional converter, and an additional control for voltage matching are required, so that a control unit is used multiple times, thus leading to problems concerning weight and cost, and making a process complicated and difficult.

Therefore, there has been a need for maximizing output of one solar cell module without including different kinds of solar cells.

### SUMMARY OF THE INVENTION

In preferred aspects, provided is an automotive solar cell roof panel which may be manufactured by adjusting the width and number of both a plurality of transparent-part cells and a plurality of opaque-part cells included in a first solar cell disposed on a center of a roof glass and a second solar cell disposed on an edge of the roof glass according to a current density and a voltage ratio, thus maximizing output of one solar cell module and a vehicle including the same.

Objectives of the present invention are not limited to the above-mentioned objectives. The objectives of the present invention may be more clearly understood by the following description. Furthermore, the objectives of the present invention may be realized by means described in claims and combinations thereof.

In an aspect, provided is an automotive solar cell roof panel that may include a first solar cell disposed on a center of a roof glass; and a second solar cell disposed on an edge of the roof glass where the first solar cell is not disposed. The first solar cell and the second solar cell may be positioned adjacent to each other, and have a gap therebetween so that the cells are not in contact with each other. The first solar cell and the second solar cell may be connected in parallel, and at least one of the first solar cell or the second solar cell may include a plurality of cells of one or more of transparent-part cells or opaque-part cells.

The term “transparent” material or “transparent” part, as used herein, may refer to a material or part having substantial transmittance of a fraction of light, such as visible light. For instance, substantial amount of visible light such as of about 50%, about 60%, about 70%, about 80%, about 90%, about 95%, about 99%, or greater thereof may transmit or pass through the transparent material or PART.

The term “opaque” material or “opaque” part, as used herein, may refer to a material blocking or screening substantial transmittance of a fraction of light, such as visible light. Alternatively, the opaque material or part may reflect substantial transmittance of a fraction of light. For instance, substantial amount of visible light such as of about 50%, about 60%, about 70%, about 80%, about 90%, about 95%, about 99%, or greater thereof may be blocked or reflected by the opaque material or part.

A width ratio of the transparent-part cell to the opaque-part cell may be in inverse proportion to a current-density ratio of the transparent-part cell to the opaque-part cell.

The current-density ratio of the opaque-part cell to the transparent-part cell may be about 0.67 to 1.5:1.

The width ratio of the opaque-part cell to the transparent-part cell may be 1:about 0.67 to 1.5.

A number of the opaque-part cells of the second solar cell may be less than a total number of cells of the first solar cell.

A number of the opaque-part cells of the second solar cell may be a value obtained by dividing a total voltage of the first solar cell by a unit voltage of the opaque-part cell of the second solar cell.

A voltage ratio of the transparent-part cell to the opaque-part cell may be 1:about 1.1 to 1.5.

The transparent-part cell or the opaque-part cell may have a structure comprising a tandem structure, and a single structure.

The transparent-part cell may have a single structure, and the opaque-part cell may have a tandem structure.

A current-density ratio of the opaque-part cell to the transparent-part cell may be about 0.67 to 1:1.

Each of the transparent-part cell and the opaque-part cell may have a single structure.

A current-density ratio of the opaque-part cell to the transparent-part cell may be about 1.1 to 1.5:1.

The opaque-part cell may include one or more metals selected from the group consisting of silver (Ag), copper (Cu), gold (Au), and aluminum (Al).

The transparent-part cell may include one or more selected from the group consisting of fluorine doped tin oxide (FTO), indium tin oxide (ITO), and zinc oxide (ZnO).

Further provided is a vehicle that may include the automotive solar cell roof panel.

An automotive solar cell roof panel according to various exemplary embodiments of the present invention is advantageous in that widths and numbers of the cells (e.g., the transparent-part cells and the plurality of opaque-part cells) are adjusted according to a current density and a voltage ratio, thus maximizing output of one solar cell module. Further, different kinds of solar cells are not used, so that an additional wiring structure for individually controlling output power, an additional converter, and additional control for voltage matching may not be required, thus simplifying a manufacturing process.

Effects of the present invention are not limited to the above-mentioned effects. It is to be understood that the effects of the invention include all effects deducible from the following description. Other aspects of the invention are disclosed infra.

### BRIEF DESCRIPTION OF THE DRAWINGS

FIG. 1 shows an exemplary front of an exemplary solar cell roof panel (10) according to an exemplary embodiment of the present invention;

FIG. 2 shows an inner region (21) and an outer region (22) of each of an exemplary first solar cell and an exemplary second solar cell in an exemplary solar cell roof panel according to an exemplary embodiment of the present invention;

FIG. 3 shows an exemplary state in which cells included in the first or second solar cell according to an exemplary the present invention are connected in series along a first axis; and

FIG. 4 shows an exemplary state in which cells included in the first and second solar cells according to an exemplary embodiment of the present invention are connected in parallel along a second axis.

### DETAILED DESCRIPTION

The above and other objects, features, and other advantages of the present invention will be more clearly understood from the following detailed description when taken in conjunction with the accompanying drawings. However, the invention should not be construed as limited to embodiments set forth herein. Rather, embodiments described herein are provided to make the disclosure thorough and complete and to fully convey the spirit of the invention to those skilled in the art.

The same reference numerals are used throughout the drawings to designate the same or similar components. In the drawings, the dimensions of components may be exaggerated for the clarity of description. It will be understood that, although the terms “first”, “second”, etc. may be used herein to describe various elements, these elements should not be limited by these terms. These terms are only used to distinguish one element from another element. For instance, a first element could be termed a second element without departing from the teachings of the present invention. Similarly, the second element could also be termed the first element. As used herein, the singular forms “a”, “an”, and “the” are intended to include plural forms as well, unless the context clearly indicates otherwise.

It will be further understood that the terms “comprises” and/or “comprising”, or “includes” and/or “including” when used in this specification, specify the presence of stated features, numbers, steps, operations, elements, components, or combinations thereof, but do not preclude the presence or addition of one or more other features, numbers, steps, operations, elements, components, or combinations thereof. Furthermore, it will be understood that when an element such as a layer, a film, a region, or a plate is referred to as being placed “on” another element, it may be placed “directly on” the other element or intervening elements may be present therebetween. In contrast, it will be understood that when an element such as a layer, a film, a region, or a plate is referred to as being placed “under” another element, it may be placed “directly under” the other element or intervening elements may be present therebetween.

Unless otherwise indicated, all numbers, values, and/or expressions referring to quantities of ingredients, reaction conditions, polymer compositions, and formulations used herein are to be understood as modified in all instances by the term “about” as such numbers are inherently approximations that are reflective of, among other things, the various uncertainties of measurement encountered in obtaining such values.

Further, unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about.”

In this specification, it is to be understood that, when a range is described for a variable, the variable includes all values within a described range including endpoints of the range. For example, it will be understood that the range of “5 to 10” includes values of 5, 6, 7, 8, 9, and 10, any sub-ranges, such as ranges of 6 to 10, 7 to 10, 6 to 9, 7 to 9, and any values between integers within the above range, such as 5.5, 6.5, 7.5, 5.5 to 8.5, and 6.5 to 9. Furthermore, for example, it will be understood that the range of “10% to 30%” includes values such as 10%, 11%, 12%, or 13%, all integers up to 30%, any sub-ranges, such as ranges of 10% to 15%, 12% to 18%, or 20% to 30%, and any values between integers within the above range, such as 10.5%, 15.5%, or 25.5%.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

Hereinafter, exemplary embodiments of the present invention will be described with reference to the accompanying drawings so that those skilled in the art can easily practice the invention.

In an aspect, provided is an automotive roof panel 10 made using a solar cell module, in which the width and the number of a plurality of transparent-part cells or a plurality of opaque-part cells are adjusted according to a current density and a voltage ratio and then the transparent-part cells or the opaque-part cells are included in first and second solar cells included in one kind of solar cell module, thus maximizing output in the solar cell module and simplifying a process.

The first solar cell 11 may be employed or disposed on the center of the roof panel, the second solar cell 12 may be employed or disposed on the edge of the roof panel. The roof glass may include laminated glass, which may be employed in place of roof glass made of conventional tempered glass, thus maximizing a photovoltaic area.

Preferably, the automotive solar cell roof panel 10 according to an exemplary embodiment of the present invention may include a laminated-glass structure, in place of the conventional tempered glass, as the roof glass to which the solar cell is attached.

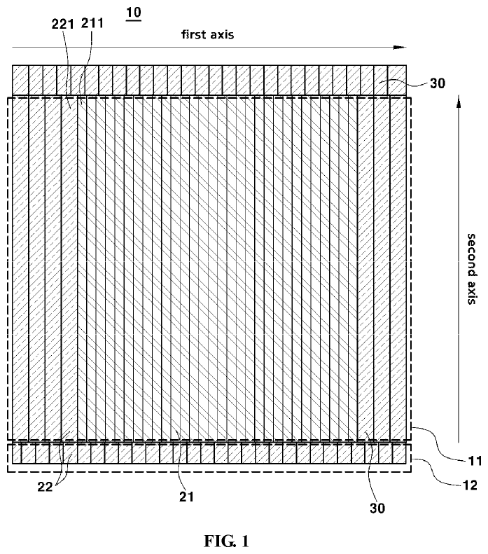

FIG. 1 illustrates an exemplary solar cell roof panel 10 according to an exemplary embodiment of the present invention. The first solar cell 11 and the second solar cell 12 may be disposed on the roof glass with an insulation structure 30 therebetween so that they may be spaced apart from each other by a predetermined gap and thus are not in contact with each other in one cell module. The first solar cell 11 and the second solar cell 12 may be connected to each other in a commonly known manner, for example, connected in series or in parallel. They may be preferably connected in parallel, or particularly connected in parallel in a ribbon form without being limited to a particular connecting method. The first solar cell 11 and the second solar cell 12 may include a plurality of cells of one or more of transparent-part cells 211 included in an inner region 21 or opaque-part cells 221 included in an outer region 22. Laminated film and roof glass may be sequentially stacked on both upper and lower surfaces of the first solar cell 11 and the second solar cell 12 (not shown). For example, the first and second solar cells may include cells that are commonly known and used, and may be one or more of solar cells selected from the group consisting of amorphous and micro-silicon solar cells, compound solar cells such as CIGS, CdTe or GaAs, Perovskite solar cells, quantum dot solar cells, organic solar cells, and combinations thereof. The solar cell may be an amorphous silicon solar cell that easily becomes translucent and tandem without being limited to a specific cell.

The roof glass may include an upper plate and a lower plate. A bonding material for bonding the roof-glass upper plate and the roof-glass lower plate may include an adhesive such as ethylene vinyl acetate (EVA), ethylene tetrafluoroethylene (ETFE), polyvinylidene fluoride (PVDF), polydimethylsiloxane (PDMS), polyethylene terephthalate (PET), or polyvinyl butyral (PVB) may be used, and the solar cell module may be attached between the upper plate and the lower plate.

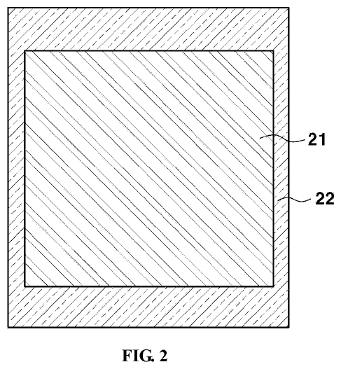

FIG. 2 illustrates the inner region 21 and the outer region 22 of each of the first solar cell and the second solar cell. Each of the first solar cell 11 and the second solar cell 12 may include any one or more of the inner region 21 or the outer region 22. Furthermore, the inner region 21 may include a plurality of transparent-part cells 211 that has high transmittance, and the outer region 22 may include opaque-part cells 221 that has low transmittance but high output. Thus, since each of the first solar cell 11 located in the center of the roof and the second solar cell 12 located in the edge of the roof may include one or more of the inner region 21 or the outer region 22, this may include a plurality of cells of any one or more of the transparent-part cells 211 or the opaque-part cells 221. Thereby, the automotive solar cell roof panel according to an exemplary embodiment of the present invention may form a high output module in one solar cell module.

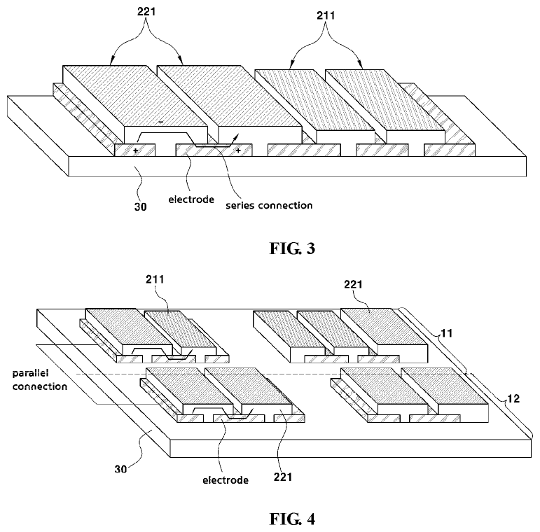

FIG. 3 is a perspective view taken along a first axis of the first or second solar cell according to an exemplary embodiment of the present invention. The transparent-part cells and the opaque-part cells may be located in the inner and outer regions included in the solar cell in the direction of the first axis. The transparent-part cells and the opaque-part cells included in the first and second solar cells may be connected in series in the direction of the first axis, and the current of the cells connected in series may be the same. Since the current of the cell is in proportion to the area of the cell and the length of the cells are equal to each other, the intensity of the current may be adjusted by the width of the cell. Therefore, the width of each of the transparent-part cells and the opaque-part cells according to exemplary embodiments of the present invention may be in inverse proportion to the current density of each of the transparent-part cells and the opaque-part cells. Since the plurality of transparent-part cells and opaque-part cells connected in series along the first axis should have the same current, a total cell current included in the first or second solar cell may be equalized by adjusting the width.

The ratio of the current density of the opaque-part cells and the transparent-part cells may vary the range of change depending on a production specification, and preferably may be about 0.67 to 1.5:1. When the current density is out of the above range, the asymmetry of the current density may increase, so that a difference in width between the opaque-part cells or the transparent-part cells may increase. For example, when the ratio is about 0.67:1 and a gap between the transparent-parts is too narrow, the scribing number and area of the cells increase, so that a power generating area may be reduced. Meanwhile, when the ratio is equal to or greater than about 1.5:1 and the gap is wide, a resistance loss may increase in one cell. Furthermore, when the opaque part is formed of a tandem cell, the current density of the tandem cell may be less than that of the single cell, and may be at least about 0.67 times as low as the single cell. Meanwhile, when the opaque part is formed of a metal electrode, it may have the current density of about 1.5 times as high as that of the transparent part.

FIG. 4 is a perspective view taken along a second axis of the first or second solar cell according to an exemplary embodiment of the present invention. The transparent-part cells and the opaque-part cells may be located in the inner and outer regions included in each of the first and second solar cells in the direction of the second axis. The first and second solar cells may be connected in parallel so that they are spaced apart from each other by a predetermined gap and thus are not in contact with each other. Since the sum of voltages of the first and second solar cells connected in parallel may be the same, the number of the opaque-part cells of the second solar cell may be equal to or smaller than a total number of the cells of the first solar cell. Preferably, the number of the opaque-part cells included in the second solar cell may be equal to a value obtained by dividing the total voltage of the first solar cell by the unit voltage of the opaque-part cell of the second solar cell. A ratio of the voltage of the transparent-part cells to voltage of the opaque-part cells may vary the range of change depending on a production specification, and preferably may be 1:about 1.1 to 1.5. When the voltage ratio is out of 1:about 1.1 to 1.5, the asymmetry of the voltage ratio may increase, so that a difference in width between the opaque-part cells or the transparent-part cells may increase. For example, when the ratio is equal to or greater than about 1:1.5, a resistance loss may increase in the transparent-part cell. When the opaque-part cell is formed of a metal electrode, its voltage may be similar to that of the transparent part. Meanwhile, when the opaque-part cell is formed of a tandem cell, two single cells may be connected in series, so that the voltage of the opaque part may always be equal to or greater than that of the transparent part.

The transparent-part cell or the opaque-part cell may include a tandem structure, a single structure, and combinations thereof.

The transparent-part cell may have a single structure, and the opaque-part cell may have a tandem structure. Preferably, a current-density ratio of the opaque-part cell having the tandem structure to the transparent-part cell having the single structure may be about 0.67 to 1.5:1, or particularly about 0.67 to 1:1. Since the width ratio of the opaque-part cell to the transparent-part cell may be about 1:0.67 to 1, the width of the opaque-part cell may be greater than the width of the transparent-part cell. The voltage ratio of the transparent-part cell having the single structure to the opaque-part cell having the tandem structure may be 1:about 1.1 to 1.5. The number of the opaque-part cells of the second solar cell including one or more transparent-part cells having the single structure and one or more opaque-part cells having the tandem structure may vary depending on the sum of a total voltage of the first solar cell and the voltage ratio of the opaque cells. Preferably, the number of the opaque-part cells of the second solar cell may be less than the total number of the cells of the first solar cell.

Furthermore, the transparent-part cell and the opaque-part cell may be a single structure. Preferably, the current-density ratio of the opaque-part cell having the single structure to the transparent-part cell having the single structure may be about 0.67 to 1.5:1, or particularly about 1.1 to 1.5:1. Since the width ratio of the opaque-part cell to the transparent-part cell may be 1:about 1.1 to 1.5, the width of the opaque-part cell may be less than the width of the transparent-part cell. Furthermore, the voltage ratio of the transparent-part cell having the single structure to the opaque-part cell having the single structure may be 1:about 1 to 1.06. Since the number of the opaque-part cells of the second solar cell including one or more transparent-part cells having the single structure and one or more opaque-part cells having the tandem structure may vary depending on the sum of a total voltage of the first solar cell and the voltage ratio of the opaque cells, and there is little in voltage-ratio difference between the transparent-part cells having the single structure and the opaque-part cells having the single structure, the number of the opaque-part cells of the second solar cell may be preferably almost equal to the total number of cells of the first solar cell.

Furthermore, when both the transparent-part cell and the opaque-part cell are the single structure, the opaque-part cell of the single structure may use a cell that is low in transmittance but is small in resistance. Preferably, the opaque-part cell may further include one or more metals selected from the group consisting of silver (Ag), copper (Cu), gold (Au), and aluminum (Al). Ag and Al that are low in transmittance but are effectively small in resistance, and a metal alloy containing Ag and Al may be included without being limited to the cell containing specific metal. Furthermore, the transparent-part cell that is of the single structure may use the cell having high transmittance, and may include one or more selected from the group consisting of fluorine doped tin oxide (FTO), indium tin oxide (ITO), and zinc oxide (ZnO).

The automotive solar cell roof panel according to various exemplary embodiments of the present invention is advantageous in that widths and numbers of the cells (e.g., the transparent-part cells and the plurality of opaque-part cells may be adjusted according to the current density and the voltage ratio, thus maximizing the output in one solar cell module, and different kinds of solar cells are not used, so that an additional wiring structure for individually controlling output power, an additional converter, and additional control for voltage matching are not required, thus simplifying a process.

### EXAMPLE

Hereinafter, the present invention will be described in detail via preferred embodiments. The following embodiments are only an example to help understanding the present invention, and the scope of the present invention is not limited thereto.

### Embodiment 1—Automotive Solar Cell Roof Panel Including First Solar Cell and Second Solar Cell Including Transparent-Part Cell of Single Structure and Opaque-Part Cell of Tandem Structure

The transparent-part cell (0.9V; 11 mA/cm²) of the single structure and the opaque-part cell (1.3V; 9 mA/cm²) of the tandem structure, which were included in the first solar cell and the second solar cell, employed the cell used in the amorphous silicon solar cell. The tandem structure was made by stacking a micro-crystalline silicon layer of 2 μm or greater on an amorphous silicon layer, and the single structure was made to include only an amorphous silicon layer. Here, the voltage ratio of the transparent-part cell to the opaque-part cell was about 1:1.4, and the current-density ratio was about 1:0.8.

Thus, the transparent-part cells and the opaque-part cells included in the first solar cell and the second solar cell were arranged in the width ratio of 0.8:1. Meanwhile, the first solar cell included 42 transparent-part cells and 8 opaque-part cells, while the opaque-part cells of the second solar cell were 38 that corresponded to a value obtained by dividing the sum of voltage of the first solar cell (1.4×8+1×42=53.2V) by 1.4V that was the unit voltage of the opaque-part cell of the second solar cell.

Thereafter, the insulation structure was formed by scribing a region between the first solar cell and the second solar cell, and PVB that was the laminated film and the roof glass were sequentially stacked on both upper and lower surfaces of the first solar cell and the second solar cell disposed on the insulation structure, thus manufacturing the automotive solar cell roof panel.

### Embodiment 2—Automotive Solar Cell Roof Panel Including First Solar Cell and Second Solar Cell Including Transparent-Part Cell of Single Structure and Opaque-Part Cell of Single Structure

The transparent-part cell (1 to 1.02V; 1 to 0.93 mA/cm²) of the single structure and the opaque-part cell (1.04V; 1.3 mA/cm²) of the single structure, which were included in the first solar cell and the second solar cell, employed the cell used in the amorphous silicon solar cell. The transparent electrode of the transparent-part cell was made to include ITO and FTO, and the opaque-part cell was made using an Ag electrode. Here, the voltage ratio of the transparent-part cell to the opaque-part cell was about 1:1, and the current-density ratio was about 1:1.3.

Thus, the transparent-part cells and the opaque-part cells included in the first solar cell and the second solar cell were arranged in the width ratio of 1.3:1. Meanwhile, the first solar cell included 52 transparent-part cells and 10 opaque-part cells, while the opaque-part cells of the second solar cell were 60 that corresponded to a value obtained by dividing the sum of voltage of the first solar cell (1×52+1.04×10=62.4V) by 1.04V that was the unit voltage of the opaque-part cell of the second solar cell.

Thereafter, the automotive solar cell roof panel was made in the same manner as embodiment 1.

As described above, according to various exemplary embodiments of the present invention, an automotive solar cell roof panel, in which first and second solar cells include a plurality of transparent-part cells and a plurality of opaque-part cells whose widths and numbers of the cells (e.g., the transparent-part cells and the plurality of opaque-part cells may be adjusted according to a current density and a voltage ratio. As such, it is unnecessary to array different kinds of solar cells with different voltage or current ranges, thus maximizing output in one solar cell module, and an additional wiring structure for individually controlling output power, an additional converter, and additional control for voltage matching are not required, thus simplifying a process.

What is claimed is:

1. An automotive solar cell roof panel, comprising:
a first solar cell disposed on a center of a roof glass; and
a second solar cell disposed on an edge of the roof glass where the first solar cell is not disposed,
wherein the first solar cell and the second solar cell are positioned adjacent to each other and have a gap therebetween so that the first solar cell and the second solar cell are not in contact with each other,
the first solar cell and the second solar cell are connected in parallel, and
at least one of the first solar cell or the second solar cell comprises a plurality of cells comprising one or more of transparent-part cells or opaque-part cells.

2. The automotive solar cell roof panel of claim 1, wherein a width ratio of the transparent-part cell to the opaque-part cell is in inverse proportion to a current-density ratio of the transparent-part cell to the opaque-part cell.

3. The automotive solar cell roof panel of claim 2, wherein the current-density ratio of the opaque-part cell to the transparent-part cell is about 0.67 to 1.5:1.

4. The automotive solar cell roof panel of claim 2, wherein the width ratio of the opaque-part cell to the transparent-part cell is 1:about 0.67 to 1.5.

5. The automotive solar cell roof panel of claim 1, wherein a number of the opaque-part cells of the second solar cell is less than a total number of cells of the first solar cell.

6. The automotive solar cell roof panel of claim 1, wherein a number of the opaque-part cells of the second solar cell is a value obtained by dividing a total voltage of the first solar cell by a unit voltage of the opaque-part cell of the second solar cell.

7. The automotive solar cell roof panel of claim 6, wherein a voltage ratio of the transparent-part cell to the opaque-part cell is 1:about 1.1 to 1.5.

8. The automotive solar cell roof panel of claim 1, wherein the transparent-part cell or the opaque-part cell has a structure comprising a tandem structure, and a single structure.

9. The automotive solar cell roof panel of claim 8, wherein the transparent-part cell has a single structure, and the opaque-part cell has a tandem structure.

10. The automotive solar cell roof panel of claim 9, wherein a current-density ratio of the opaque-part cell to the transparent-part cell is about 0.67 to 1:1.

11. The automotive solar cell roof panel of claim 8, wherein each of the transparent-part cell and the opaque-part cell has a single structure.

12. The automotive solar cell roof panel of claim 11, wherein a current-density ratio of the opaque-part cell to the transparent-part cell is about 1.1 to 1.5:1.

13. The automotive solar cell roof panel of claim 11, wherein the opaque-part cell comprises one or more metals selected from the group consisting of silver (Ag), copper (Cu), gold (Au), and aluminum (Al).

14. The automotive solar cell roof panel of claim 11, wherein the transparent-part cell comprises one or more selected from the group consisting of fluorine doped tin oxide (FTO), indium tin oxide (ITO), and zinc oxide (ZnO).

15. A vehicle comprising an automotive solar cell roof panel of claim 1.
